(19) United States
(12) Patent Application Publication
(10) Pub. No.: US 2013/0329760 A1
(43) Pub. Date: Dec. 12, 2013

(54) SEMICONDUCTOR LASERS WITH INDIUM CONTAINING CLADDING LAYERS

(71) Applicants: Rajaram Bhat, Painted Post, NY (US); Dmitry Sergeevich Sizov, Corning, NY (US); Chung-En Zah, Holmdel, NJ (US)

(72) Inventors: Rajaram Bhat, Painted Post, NY (US); Dmitry Sergeevich Sizov, Corning, NY (US); Chung-En Zah, Holmdel, NJ (US)

(73) Assignee: CORNING INCORPORATED

(21) Appl. No.: 14/000,973

(22) PCT Filed: Feb. 2, 2012
(86) PCT No.: PCT/US2012/023629

§ 371 Date: Aug. 22, 2013

Related U.S. Application Data
(60) Provisional application No. 61/447,245, filed on Feb. 28, 2011.

(51) Int. Cl. H01S 5/343

(52) U.S. Cl. CPC H01S 5/343
USPC 372/44.011; 372/45.01; 372/45.012

(57) ABSTRACT

An embodiment of semiconductor laser comprising: (a) a GaN, AlGaN, InGaN, or AlN substrate; (b) an n-doped cladding layer situated over the substrate; (c) a p-doped cladding layer situated over the n-doped; (d) at least one active layer situated between the n-doped and the p-doped cladding layer, and at least one of said cladding layers comprises a superstructure structure of AlInGaN/GaN, AlInGaN/AlGaN, AlInGaN//InGaN or AlInGaN/AlN with the composition such that the total of lattice mismatch strain of the whole structure does not exceed 40 nm %.

### BACKGROUND

This application claims the benefit of priority of U.S. Provisional Application Ser. No. 61/447,245 filed Feb. 28, 2011.

The disclosure relates generally to optoelectronic semiconductor devices, and more particularly to GaN-based semiconductor lasers with indium (In) containing cladding layers.

GaN-based lasers are often grown on the polar plane of a GaN substrate, which imposes strong internal fields that can hamper electron-hole recombination needed for light emission. However, growing on the c-plane high quality QW (quantum well) for LDs (laser diodes) emitting in green spectral range is challenging because of the very tight requirements of QW design and growth tolerances (i.e., small tolerances), and unique equipment required.

GaN substrates can also be cut along semi-polar crystal planes, creating much weaker internal fields and allowing for high quality active regions (high quality quantum wells, relative to those on substrates cut along the c-planes) with high indium (In) content, which can stretch emission wavelengths to green with fewer crystal growth challenges. Such substrates can be utilized in conjunction with bulk (e.g., larger than 100 nm, for example 1 μm or more) thickness AlGaN or AlGaInN n-and-p cladding layers to form green lasers. But when the bulk AlGaN layers are grown thereon, these cladding layers tend to relax by gliding if threading dislocations are present in the substrate when the strain-thickness product of the cladding layer(s) is high enough. In addition, the layers tend to crack to relieve strain. This happens because of the need for a thick layer, which is dictated by the requirement to form a waveguide sufficiently thick to confine light within the layers. When the strain-thickness product of the cladding layer(s) exceeds a critical value (in order to confine light within the layers) misfit dislocation is likely to occur.

AlGaInN cladding layers can also be utilized with the GaN substrates cut along semi-polar crystal planes, because indium atoms enable good lattice matching between the cladding layers and the substrate, which prevents relaxation and thus tends to prevent misfit dislocations. However, highly conductive p-type bulk AlGaInN cladding layers are difficult to grow to due to the low growth temperatures (below 800° C.) required in to incorporate indium (In) into these layers. In addition, the specific growth conditions for each composition of bulk AlGaInN layer has to be established, and this requires many experimental growth runs, which adds to the manufacturing costs.

No admission is made that any reference cited or described herein constitutes prior art. Applicant expressly reserves the right to challenge the accuracy and pertinency of any cited documents.

### SUMMARY

One embodiment of the disclosure relates to a semiconductor laser comprising:
(a) GaN, AlGaN, InGaN, or AN substrate;
(b) an n-doped cladding layer situated over the substrate;
(c) a p-doped cladding layer situated over the n-doped cladding layer;
(d) at least one active layer situated between the n-doped cladding layer and the p-doped cladding layer, wherein
the at least one of the cladding layers contains indium and comprises a superstructure of quaternary/binary, ternary/binary and/or quaternary/ternary sublayers.

According to some embodiments:
(i) the total lattice mismatch strain of the whole superstructure of the cladding layer relative to said substrate does not exceed 40 nm %; and/or
(ii) the total lattice mismatch strain of the semiconductor laser structure that is situated below the at least one cladding layer does not exceed 40 nm %; and or
(iii)) the total lattice mismatch strain of the semiconductor laser structure that is situated below any higher cladding layer does not exceed 40 nm %; and/or
(iii) the total lattice mismatch strain of the semiconductor laser structure does not exceed 40 nm %.

For example, according to one embodiment the laser comprises: (a) GaN, AlGaN, InGaN, or AlN substrate; (b) an n-doped cladding layer situated over the substrate; (c) a p-doped cladding layer situated over the n-doped cladding layer; (d) at least one active layer situated between the n-doped and the p-doped cladding layers, and at least one of the cladding layers comprises a super structure of AlInGaN/GaN, AlInN/GaN, AlInGaN/AlGaN, AlInGaN//InGaN, or AlInGaN/AlN with the composition chosen such that the total lattice mismatch strain of the whole super structure does not exceed 40 nm %.

An additional embodiment of the disclosure relates to a semiconductor laser comprising:
(i) a GaN, AlGaN, InGaN, or AlN substrate;
(ii) an n-doped cladding layer situated over the substrate;
(iii) a p-doped cladding layer situated over the n-doped cladding layer;
(iv) at least one active layer situated between the n-doped and the p-doped cladding layers,

wherein at least one of said cladding layers comprises (a) an indium containing superlattice structure of AlInGaN/GaN, AlInN/GaN, AlInGaN/AlGaN, AlInGaN/InGaN, AlInGaN/AlN; or (b) AlInN/GaN ternary/binary superstructure.

According to some embodiments the substrate is GaN, and at least one of the cladding layer is an indium containing periodic structure (for example a quaternary/binary superstructure). According to some embodiments the substrate is GaN and the n-cladding layer is a superlattice-structure of AlInGaN/GaN.

Particular embodiments of the present disclosure relate to growth on the (20 2̅1) crystal plane of a GaN substrate, in which case the GaN substrate can be described as defining a (20 2̅1) crystal growth plane.

Additional features and advantages will be set forth in the detailed description which follows, and in part will be readily apparent to those skilled in the art from the description or recognized by practicing the embodiments as described in the written description and claims hereof, as well as the appended drawings.

It is to be understood that both the foregoing general description and the following detailed description are merely exemplary, and are intended to provide an overview or framework to understand the nature and character of the claims.

The accompanying drawings are included to provide further understanding, and are incorporated in and constitute a part of this specification. The drawings illustrate one or more embodiment(s), and together with the description serve to explain principles and operation of the various embodiments.

### BRIEF DESCRIPTION OF THE DRAWINGS

FIG. 1 illustrates schematically a GaN laser according to some embodiments of the present invention;

FIG. 2 illustrates the RSM (reciprocal space map) of a laser illustrated in FIG. 1;

FIG. 3 is a plot of optical mode intensity and its penetration of the p-metal contact for GaN lasers with p-side cladding thickness of 550 nm to 950 nm;

FIG. 4 is a plot of the optical mode intensity and refractive index profile for an embodiment of a GaN laser with p-side cladding thickness of 950 nm, and n-side cladding comprising n-AlInGaN/GaN superstructure;

FIG. 5A illustrates optical loss for the laser structure with a relatively thick p-cladding layer that corresponds to the embodiment of FIG. 2;

FIG. 5B illustrates performance (CW output power) of the LD structure that also corresponds to the embodiment of FIG. 2;

FIG. 6A illustrates optical loss for the laser that has a p-cladding layer of relatively low thickness (595 nm);

FIG. 6B is a light output power vs. current graph for the LD structure of laser associated with FIG. 6A; and

FIG. 7 illustrates the RSM (reciprocal space map) of a comparative GaN laser.

### DETAILED DESCRIPTION

Disclosed are materials, compounds, compositions, and components that can be used for, can be used in conjunction with, can be used in preparation for, or are products of the disclosed method and compositions. These and other materials are disclosed herein, and it is understood that when combinations, subsets, interactions, groups, etc. of these materials are disclosed that while specific reference of each various individual and collective combinations and permutation of these compounds may not be explicitly disclosed, each is specifically contemplated and described herein. Thus, if a class of substituents A, B, and C are disclosed as well as a class of substituents D, E, and F and an example of a combination embodiment, A-D is disclosed, then each is individually and collectively contemplated. Thus, in this example, each of the combinations A-E, A-F, B-D, B-E, B-F, C-D, C-E, and C-F are specifically contemplated and should be considered disclosed from disclosure of A, B, and C; D, E, and F; and the example combination A-D. Likewise, any subset or combination of these is also specifically contemplated and disclosed. Thus, for example, the sub-group of A-E, B-F, and C-E are specifically contemplated and should be considered disclosed from disclosure of A, B, and C; D, E, and F; and the example combination A-D. This concept applies to all embodiments of this disclosure including, but not limited to any components of the compositions and steps in methods of making and using the disclosed compositions. Thus, if there are a variety of additional steps that can be performed it is understood that each of these additional steps can be performed with any specific embodiment or combination of embodiments of the disclosed methods, and that each such combination is specifically contemplated and should be considered disclosed.

It will be further understood that the endpoints of each of the ranges are significant both in relation to the other endpoint, and independently of the other endpoint.

### Definitions:

Superstructure. A superstructure is a structure of alternating layers of at least two different materials with layer thicknesses that are small (60 nm or less) compared to the wavelength of light in the ultraviolet to green range. A super structure may be periodic or non-periodic.

Superlattice. A superlattice is a structure (superstructure) of alternating layers of at least two different materials with layer thickness comparable with electron and hole wavelengths in the material, such that the layer thickness that is 4 nm or less. A superlattice structure may be periodic or non-periodic.

Refractive index contrast between the cladding layers and a waveguiding layer is the difference between the average refractive index n_{c} of the cladding layer and the average refractive index n_{w} of the adjacent waveguiding layer (i.e., Δ=|n_{c}−n_{w}|), at the operating wavelength λ, wherein λ is about 530 nm (500 nm≦λ≦565 nm). For example, the average refractive index n_{c} of the cladding layer is ΣnᵢLᵢ/ΣLᵢ, where the cladding layer a plurality of sublayers, i is an integer, corresponding to the sublayer number within the cladding layer, nᵢ is the refractive index of the given sublayer, and Lᵢ is the thickness of the given sublayer.

Some embodiments of the semiconductor laser comprise: (a) GaN, AlGaN, InGaN, or AlN substrate; (b) an n-doped cladding layer situated over the substrate; (c) a p-doped cladding layer situated over the n-doped cladding layer; and (d) at least one active layer situated between the n-doped and the p-doped cladding layers. At least one of the cladding layers contains indium and comprises a structure of alternating thin (less than or equal to 60 nm, each, for example 50 nm, 45 nm, 40 nm, 35 nm, 30 nm, 25, nm, 20 nm, or thinner) sublayers, forming either a periodic or a non-periodic structure. For example, at least one of the cladding layers may be a superstructure and/or a superlattice structure that includes indium (In). For example, at least one of the cladding layers can comprise an indium (In) containing quaternary/binary, ternary/binary or quaternary/ternary superstructure or a superlattice structure.

According to these embodiments the cladding layer(s) may comprise at least one of the following pairs of sub-layers: AlInGaN/GaN, AlInN/GaN, AlInGaN/AlGaN, AlInGaN//InGaN or AlInGaN/AlN, or a combination of these pairs.

For example, in some embodiments at least one of the cladding layers comprises an indium containing quarternary/binary, quaternary/ternary or ternary/binary superlattice structure and the total lattice mismatch strain of the whole structure of this cladding layer(s), relative to the substrate, does not exceed 40 nm %. In at least some embodiments the total lattice mismatch strain of the whole structure of this cladding layer(s) does not exceed 35 nm % (e.g., it is about 30 nm % or less).

Preferably, according to at least some of the embodiments, the total lattice mismatch strain of the whole structure of the laser (relative to the substrate) does not exceed 40 nm %. In at least some embodiments the total of lattice mismatch strain the whole laser structure does not exceed 35 nm % (e.g., it is about 30 nm % or less).

Also, preferably, according to at least some of the embodiments, the total lattice mismatch strain of the laser structure that is situated below any given layer does not exceed 40 nm %. Preferably, according to at least some of the embodiments, the total lattice mismatch strain of the laser structure situated below any given layer does not exceed 35 nm % (e.g., it is about 30 nm % or less).

Preferably, according to at least some embodiments, the at least one of the cladding layers that includes In and comprises an alternating (e.g., periodical structure) of AlInGaN/GaN, AlInN/GaN, AlInGaN/AlGaN, AlInGaN//InGaN or AlInGaN/AlN (or a combination thereof) has a composition such that the total lattice mismatch strain of the whole structure of this cladding layer(s) does not exceed 40 nm %.

According to some embodiments the substrate is GaN, and at least one cladding layer is a quaternary/binary superstructure which may be a superlattice (SL) structure. For example, according to some embodiments the substrate is GaN and the n-cladding layer is a superlattice-structure of AlInGaN/GaN. At least some of the particular embodiments of the present disclosure relate to growth on the semipolar plane of a GaN substrate, for example on the (20 2̅1) crystal plane of a GaN substrate, in which case the GaN substrate can be described as defining a (20 2̅1) crystal growth plane. Alternatively, other semipolar planes of a GaN substrate may also be utilized, for example semipolar planes situated at or is within 10 degrees of the following crystal growth planes: (11-22), (11-2-2), (20-21), (20-2-1), (30-31), or (30-3-1). Preferably, the semiconductor laser is configured to emit at the operating wavelength λ, where 500 nm≦λ≦565 nm, more preferably 510 nm≦λ≦540 nm.

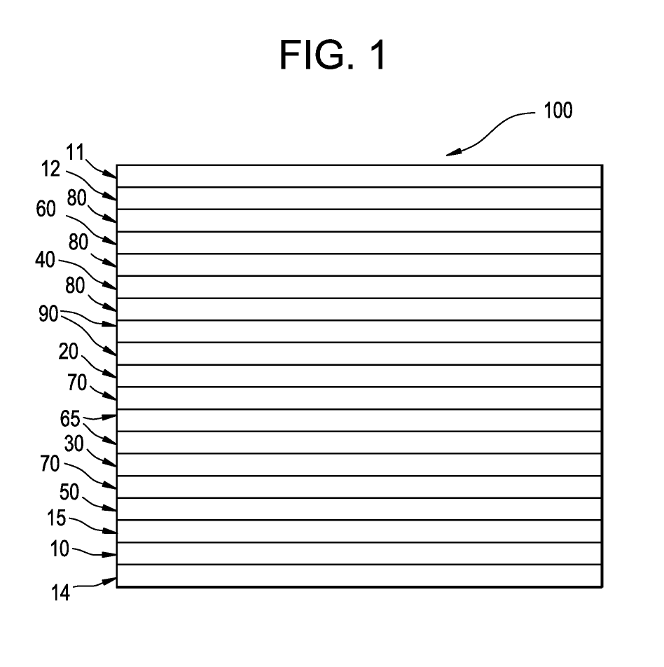

Referring collectively to the embodiments illustrated in FIG. 1, exemplary GaN edge emitting lasers 100 according to the present disclosure comprise a semi-polar GaN substrate 10, an optional buffer layer 15, an active region 20, an n-side waveguiding layer 30, a p-side waveguiding layer 40, an n-type cladding layer 50, and a p-type cladding layer 60 (also referred to herein as the p-doped cladding layer, or p-side cladding layer) and optional hole blocking layers 65. The GaN substrate 10, which may define a (20 2̅1) or other semi-polar crystal growth plane, may have threading dislocation density on the order of approximately 1×10⁶/cm², i.e., above 1×10⁵/cm² but below 1×10⁷/cm². Alternatively, The GaN substrate 10 may have a dislocation density between 1×10²/cm² and 1×10⁵ cm². As illustrated in FIG. 1, the active region 20 is interposed between and extends substantially parallel to the n-side waveguiding layer 30 and the p-side waveguiding layer (WG) 40. The n-type cladding layer 50 (also referred herein as the n-doped cladding layer or the n-side cladding layer) is interposed between the n-side waveguiding layer (WG) 30 and the GaN substrate 10. The p-type cladding layer 60 is formed over the p-side waveguiding layer 40. An exemplary GaN edge emitting laser 100, according to the present disclosure can also contain at least one spacer layer 80, 70, which may be situated, for example, between the p-side waveguiding layer 40 and the p-type cladding layer 60 and/or between the n-side waveguiding layer 30 and the n-type cladding layer 50. An electron blocking layer (EBL), 90 may also be present, for example between the MQW layer 20 and the p-side waveguiding layer 40. Finally, in embodiments of FIG. 1 an n-side spacer layer 70 is situated between the n-type cladding layer 50 and the n-side waveguiding layer 30, and a p-side spacer layer 80 is situated between the p-type waveguiding layer 40 and the p-type cladding layer 60. Metal layers 11 (p-side) and 14 (n-side) are present above the p-type cladding layer 60 and below the substrate layer 10, respectively.

The Matthews-Blakeslee equilibrium theory, which is well documented in the art, provides predictions of the critical thickness of a strained hetero-epitaxial layer for the onset of misfit dislocations. According to the theory, relaxation via misfit dislocation generation occurs if the layer thickness exceeds the Matthews-Blakeslee critical thickness of the layer. The mathematical product of this thickness and the strain in the layer is referred to herein as the strain-thickness product of the layer. Applicants discovered that preferably the strain-thickness product for the layer should not exceed 40 nm %, and more preferably should not exceed 30 nm %. Higher index contrast is desired for mode guiding, and if the cladding layer contains Al, the index contrast between this cladding layer and the nearest waveguiding layer increases with the increase in Al concentration. However, this also increases the strain thickness product. Thus, according to at least some of these embodiments, the average refractive index contrast between the cladding layer and the nearest waveguiding layer is at least 0.01 (and, according to at least some embodiments, preferably 0.02-0.03), and the total of lattice mismatch strain of the whole laser structure, relative to the substrate does not exceed 40 nm %. Preferably, total lattice mismatch strain of the whole laser structure does not exceed 35 nm %, and more preferably is not larger than 30 nm %.

For example, an embodiment of the GaN semiconductor laser 100 may utilize, as its n-type cladding layer 50, a super structure (SS) of alternating 7.7 nm AlGaInN and 23 nm GaN sublayers (i.e., 7.7 nm AlGaInN/23 nm GaN); and for the p-type cladding layer 60 a superstructure (SS) structure of alternating 2.5 nm AlGaN and 7.5 nm GaN sublayers (i.e., 2.5 nm AlGaN/7.5 nm GaN). The AlGaInN composition of the cladding layers 50, 60 is chosen, for example, to give a photoluminescence emission peak at 336 nm, while lattice matching it to GaN along the a-crystallographic direction. In this embodiment, the waveguide layers 30 and 40 comprise a superlattice (SL) of alternating 2 nm thick (each) GaInN and 4 nm thick (each) GaN sublayers (e.g., 2 nm Ga_{0.88}In_{0.12}N/4 nm GaN). For this embodiment the average refractive index contrast between the cladding layer 50, 60 and the nearest waveguiding layer 30, 40 is about 0.025).

Overall, the average refractive index of the n- and p-cladding layers does not have to be the same. For some designs it is preferred to have lower refractive index in n-cladding layer (via using higher fraction of AlInN in the AlInGaN material). The stronger index contrast from the n-cladding layer allows minimizing optical mode leakage to the substrate. Minimization of optical leakage can minimize optical losses and ensure good far field pattern.

Various embodiments will be further clarified by the following examples.

### Example 1

In these exemplary embodiments of GaN semiconductor laser, the AlGaInN/GaN superstructures (SS) and/or superlattice-structures (SLS) are used for the n-type cladding 50 and the p-type cladding 60, with the active layer 20 comprising multiple quantum wells (MQW) sandwiched between the n-type cladding 50 and the p-type cladding 60. The active layer 20 of these embodiments comprises, for example, GaInN/GaN/AlGaInN. In addition, these embodiments also utilize the n-side hole blocking layers 65 comprising n-AlGaInN/n-AlGaN or n-AlGaN or a combination thereof, and p-side electron blocking layers 90 comprising, for example, p-AlGaN, or p-AlGaN/p-AlGaInN, or p-AlGaN/p-AlGaInN.

As discussed above, an exemplary GaN laser corresponding to Structure 1 may utilize claddings comprising an AlGaInN/GaN super structure (SS). This enables lattice matching (relative to the substrate) in one in-plane (the plane parallel to the substrate plane) direction and strain minimization in the perpendicular direction (i.e., perpendicular to the one direction, in that plane) to avoid misfit dislocation formation. It is noted that any composition of GaN and AlInN that is lattice matched (in one direction) to GaN can be utilized for the AlGaInN containing cladding layer to obtain the desired refractive index (and thus the desired refractive index contrast with the waveguiding layer). However, because higher AlInN content tends to degrade electrical conductivity, one may select between having lower refractive index (i.e., more Al due to higher AlInN content) or having higher electrical conductivity (i.e., less Al due to lower AlInN content). Thus, because of the tradeoff between the refractive index contrast and conductivity s, one can select between the optimum combination of refractive index contrast and conductivity, based on the specific requirements for the laser. In addition, the average refractive index of the cladding layers that include a AlGaInN/GaN superstructure can be controlled by the proper choice of the ratio(s) of the AlGaInN sub-layer thickness to GaN sub-layer thickness. Preferably, the ratio of AlGaInN sublayer thickness to that of GaN in the cladding layer(s) is 1:2 to 1:4, for example 1:2.5 to 1:3.5, or 1.28 to 1.36. Exemplary thicknesses for AlGaInN and GaN sublayers in the superstructures forming the cladding(s) are be about 7-10 nm (AlGaInN) and about 20-24 nm (GaN), respectively; or about 2-3 nm (AlGaInN) to about 7-10 nm (GaN), respectively. In some embodiments, the composition of the AlGaInN layer is chosen to provide a photoluminescence emission wavelength of 336 nm at room temperature (22° C.). However, the photoluminescence emission wavelength can be chosen to be shorter or longer (e.g., 330 nm, 340 nm or 350 nm), depending on the overall design; and layer thickness and thickness ratio can be varied as desired. Such superstructures give more freedom in the growth parameters, which helps improve the crystal quality of the cladding layers. (Note: The shorter photoluminescence (PL) emission wavelengths correspond to lower refractive index and the longer photoluminescence emission wavelengths correspond to higher refractive index. (Photoluminescence emission wavelength is an indication of the band gap—higher band gaps correspond to the shorter photoluminescence emission wavelengths—and the refractive index is a function of the bandgap, with higher bandgap corresponding to the lower refractive index.) Thus, the photoluminescence emission wavelength can be chosen based on the refractive index contrast needed between the cladding and waveguide layers.

More specifically, at least some of the exemplary embodiments according to Structure 1 comprise the following layers:

Structure 1

p-side Metal layer, 11
p-side Contact layer 12: p⁺ or p⁺⁺ GaN, 10-30 nm
p-side spacer layer, 80: GaN, 10-100 nm (optional layer)
p-side cladding, layer 60: AlₓGa_{y}In_{(1-x-y)}N/GaN,
total TH = 0.5 to 2 micron, preferably 0.6 to 1 micron (preferably In <19
mole %)
p-side spacer, layer 80: GaN, TH = 5-200 nm (optional layer)
p-side SL waveguide, layer 40: GaInN and/or GaInN/GaN; and/or passive
MQW WG layer 40′, Th = 50-130 nm
p-side EBL 90: P-AlGaN, TH = 10-30 nm, Al % = 10-30 mole %
(optional layer) active layer 20, MQWs,
n-side HBL 65: AlGaInN or AlGaN or both, 10-30 nm, Al % = 5-30
mole % (optional layer)
n-side SL 30: GaInN and/or GaInN/GaN; and/or WG 30′: n-passive MQW;
total Th = 60-130 nm
n-side Spacer layer 70: GaN, total TH = 5-200 nm (optional layer) yes
N-cladding, layer 50: AlₓGa_{y}In_{(1-x-y)}N/GaN, total TH = 1-2 microns
n-side Bufer layer, 15: GaN, 10 nm to greater than 5 microns
Semipolar GaN Substrate 10 (eg. (20-21)); total Th = 60-90 microns
n-side - Metal, layer 14

In this table “Th” stands for the total thickness of the given layer (i.e., the sum of the thickness of the corresponding sub-layers), x is a positive number below 1, and y is either a positive number below 1 or is zero, and the p⁺ symbol indicates that the layer is heavily doped with acceptors such as Mg, Be or Zn to provide p-side conductivity. For example, if Mg is utilized, the amount of Mg in p-side contact layer 12 is preferably at least 10¹⁸/cm³ (e.g., 10¹⁹/cm³, 10²⁰/cm³). The p⁺⁺ symbol indicates that the layer is more heavily doped with acceptors than the layer associated with the p⁺ layer. (The + sign means the layer contains relatively high concentration of the p-type dopant. The more + signs, the higher the level of the p-type dopant, relative to the other layers). Exemplary n-side acceptor dopants include Si (for example in the amounts of 2×10¹⁸ to 5×10¹⁸/cm³) and/or Ge.

According to at least some embodiments, concentrations for Al, In and Ga in the cladding layer 50 and 60 of the GaN laser examples according to Structure 1 are: Al 8-82 mole %; Ga 0-90 mole %; In 2-18 mole %. For example, in some embodiments the amount of Al is 20.8 mole %, the amount of Ga is 74.64 mole %, and the amount of In is 4.56 mole %. In another embodiment, the amount of Al is 82 mole %, the amount of Ga is 0 mole % (i.e., no Ga is present), and the amount of In is about 18 mole %. It is noted that the structure of cladding layers 50 and 60 does not have to be identical (i.e., x and y numbers corresponding to the layer 50 do not have to be identical to the x and y numbers corresponding to layer 60).

Table 1, below, provides the constructional parameters of the first exemplary embodiment corresponding to Structure 1. This embodiment is illustrated in FIG. 1.

TABLE 1

| Layer | Thickness | | Composition | Doping | Comments |
|---|---|---|---|---|---|
| p-side Metal, | | | | | |
| layer 11 | | | | | |
| p-side Contact, | 25 | nm | GaN | p⁺⁺ doped | |
| 12 | | | | | |
| p-side spacer, | 66 | nm | GaN | p⁺ doped | |
| layer 80 | | | | | |
| p-side SS | 620 | nm | (2.5 nm AlGaInN/7.5 nm | p doped | The AlGaInN |
| cladding, 60 | | | GaN) × 62 | | composition is such |
| | | | | | that it is lattice |
| | | | | | matched to GaN in |
| | | | | | the a-direction and |
| | | | | | has a PL emission |
| | | | | | wavelength of 336 nm |
| p-side spacer, | 51 | nm | GaN | p doped | |
| layer 80 | | | | | |
| p-side SL | 90 | nm | (2 nm Ga_{0.88}In_{0.12}N/4 nm | p doped | |
| waveguide, 40 | | | GaN) × 15 | | |
| p-side spacer, | 5 | nm | GaN | p doped | Optional |
| layer 80 | | | | | |
| Electron Block | 10 | | Al_{0.28}Ga₇₂N | p⁺ doped | |
| (EBL), 90 | | | | | |
| Electron Block | 8 | nm | Al_{0.05}Ga_{0.93}In_{0.02}N | p⁺ doped | Optional |
| (EBL), 90 | | | | | |
| MQW active | 50.8 | nm | (3.5 nm Ga_{0.7}In_{0.3}N | Undoped | For example 2-5 |
| region, 20 | | | 3.3 nm GaN/ | | QWs |
| | | | 8 nmAl_{0.05}Ga_{0.93}In_{0.02}N/ | | |
| | | | 3.3 nm GaN) × n, | | |
| | | | where n is 2 to 10, | | |
| | | | preferably 2-5 | | |
| n-side spacer, | 13.7 | nm | GaN | n doped | Optional |
| layer 70 | | | | | |
| n-side Hole | 10 | nm | Al_{0.28}Ga₇₂N | n doped | Optional |
| Block layer | | | | | |
| (HBL), 65 | | | | | |
| n-side Hole | 8 | nm | Al_{0.05}Ga_{0.93}In_{0.02}N | n doped | Optional |
| Block layer | | | | | |
| (HBL), 65 | | | | | |
| n-side SL, 30 | 126 | nm | (2 nm Ga_{0.88}In_{0.12}N/4 nm | n doped | |
| waveguide | | | GaN) × 21 | | |
| n-side spacer, | 77 | nm | GaN | n doped (for | |
| 70 | | | | example with | |
| | | | | Si or Ge) | |
| n-side SS | 1016.4 | nm | (23.1 nm GaN/7.7 nm | n doped | The AlGaInN |
| cladding, 50 | | | AlGaInN) × 33 | | composition is such |
| | | | | | that it is lattice |
| | | | | | matched to GaN in |
| | | | | | the a-direction and |
| | | | | | have a PL emission |
| | | | | | of 336 nm |
| Buffer, 15 | 1050 | nm | GaN | n doped | |
| Substrate, 10 | 80 | microns | GaN | n doped | Orientation: (20-21) |
| n-side Metal, | | | | | |
| layer 14 | | | | | |

### Example 2

In these embodiments, no or very little indium (less than 0.5 mole %) is utilized in p-side cladding layer 60, compared to the n-side cladding layer 50. Because of this, the embodiments of Example 2 provide better conductivity than embodiments of Example 1. Better conductivity on the p-side is beneficial because it results in a lower voltage drop across this layer. Structure 2 (shown below) provides exemplary constructional parameters of Example 2 embodiments. Structure 2 embodiments also correspond to FIG. 1. Exemplary embodiments according to Structure 2 utilize an AlGaInN/GaN layer (a superstructure or a super lattice structure) on the n-side (n-type cladding layer 50) and an AlGaN/GaN (a superstructure or a super lattice structure) on the p-side (i.e., p-type cladding layer 60).

As in the previously described embodiments of example 1, optional hole blocking layers 65, for example of n-AlGaInN or n-AlGaN or a combination thereof are utilized in the example 2 embodiments. At least some of the exemplary embodiments of GaN based semicoductor lasers according Structure 2 comprise the following layers:

Structure 2

p-side Metal layer, 11
p-side Contact layer 12: p⁺ GaN, total TH = 10-30 nm
p-side spacer layer, 80: GaN, total TH = 10-100 nm (optional)
p-side cladding, layer 60: AlGaN/GaN, SL, total TH = 0.5-1 micron
p-side spacer, layer 80: GaN, total TH = 5-200 nm (optional)
p-side SL waveguide, layer 40: GaInN and/or GaInN/PGaN, SL; and/or
passive MQW WG 40′, total total TH = 50-130 nm
p-side EBL 90: AlGaN, total Th = 10 nm-30 nm, Al % = 10-30 mole %
(optional) active layer 20, MQWs
n-side HBL 65: AlGaInN or AlGaN or both, total Th = 10-30 nm,
Al % = 5-30% (optional)
n-side SL 30: GaInN and/or GaInN/GaN SL; and/or passive MQW WG,
total Th = 60-130 nm
n-side Spacer layer 70: GaN, 5-200 nm (optional)
n-side cladding, layer 50: AlₓGa_{y}In_{(1-x-y)}N/GaN, SS,
total TH = 1-2 microns
n-side Bufer layer, 15: GaN, 10 nm to greater than 5 microns
Substrate 10: Semipolar GaN (eg. (20-21); total TH = 60-90 microns
n-side layer 14: Metal layer

In this table “Th” stands for the total thickness of the given layer (i.e., the sum of the thickness of the corresponding sub-layers), x is a positive number below 1, and y is either a positive number below 1 or is zero, and the p⁺ symbol indicates that the layer is heavily doped with acceptors such as Mg, Be or Zn to provide p-side conductivity.

According to at least some embodiments, the range for Al, In and Ga for the cladding layers 50 of the examples according to Structure 2 are: Al 8-82 mole %; Ga 0-90 mole %; and In 2-18 mole %. For example, in some embodiments the amount of Al is 20.8 mole %, the amount of Ga is 74.64 mole % and the amount of In is 4.56 mole %. In another embodiment the amount of Al in the cladding layers 50 is 82 mole %, the amount of Ga is 0 mole % (i.e., no Ga is present), and the amount of In is about 18 mole %.

Table 2A, shown below, provides the constructional parameters of the one exemplary embodiment corresponding to Structure 2 (second exemplary embodiment).

TABLE 2A

| Layer | Thickness | | Composition | Doping | Comments |
|---|---|---|---|---|---|
| n-Metal, Layer 11 | | | | | |
| p-Contact, layer 12 | 25 | nm | GaN | p⁺⁺ doped | |
| p-spacer layer, 80 | 66 | nm | GaN | p⁺ doped | |
| p-SL cladding, layer | 895 | nm | (2.5 nm | p doped | In some |
| 60 | | | Al_{0.1}Ga_{0.9}N/2.5 nm | | embodiments this |
| | | | GaN) × 179 | | layer may |
| | | | | | comprise bulk p- |
| | | | | | Al_{0.05}Ga_{0.95}N layer |
| p-spacer, layer 80 | 51 | nm | GaN | p doped | |
| p-SL waveguide, | 90 | nm | (2 nm Ga_{0.88}In_{0.12}N/4 nm | p doped | |
| layer 40 | | | GaN) × 15 | | |
| p-spacer, layer 80 | 5 | nm | GaN | p doped | Optional |
| Electron Block | 10 | | Al_{0.28}Ga₇₂N | p⁺ doped | |
| (EBL), 90 | | | | | |
| Electron Block | 8 | nm | Al_{0.05}Ga_{0.93}In_{0.02}N | p⁺ doped | Optional |
| (EBL) 90 | | | | | |
| active layer 20, | 50.8 | nm | (3.5 nm | Undoped | Can have, for |
| (MQW active | | | Ga_{0.7}In_{0.3}N/3.3 nm | | example, 2 to 3 |
| region) | | | GaN/8 nm | | QWs |
| | | | Al_{0.05}Ga_{0.93}In_{0.02}N/3.3 nm | | |
| | | | GaN) × n, where | | |
| | | | n is an integer and | | |
| | | | n = 2 to 10, preferably | | |
| | | | 2 to 5 | | |
| n-spacer, layer 70 | 13.7 | nm | GaN | n doped | Optional |
| Hole Block (HBL), | 10 | | Al_{0.28}Ga₇₂N | n doped | Optional |
| layer 65 | | | | | |
| Hole Block (HBL), | 8 | nm | Al_{0.05}Ga_{0.93}In_{0.02}N | n doped | Optional |
| layer 65 | | | | | |
| n-side SL | 126 | nm | (2 nm Ga_{0.88}In_{0.12}N/4 nm | n doped | |
| waveguide, layer 30 | | | GaN) × 21 | | |
| n-spacer, layer 70 | 77 | nm | GaN | n doped | |
| n-side SS cladding, | 1016.4 | nm | (23.1 nm GaN/7.7 nm | n doped | The AlGaInN |
| layer 50 | | | AlGaInN) × 33 | | composition is |
| | | | | | such that it is |
| | | | | | lattice matched to |
| | | | | | GaN in the a- |
| | | | | | direction and has a |
| | | | | | PL emission of |
| | | | | | 336 nm |
| Buffer, 15 | 1050 | nm | GaN | n doped | |
| Substrate, 10 | 80 | microns | GaN | n doped | (20-21) |
| | | (60-90 | | | |
| | | microns) | | | |
| n-Metal, 14 | | | | | |

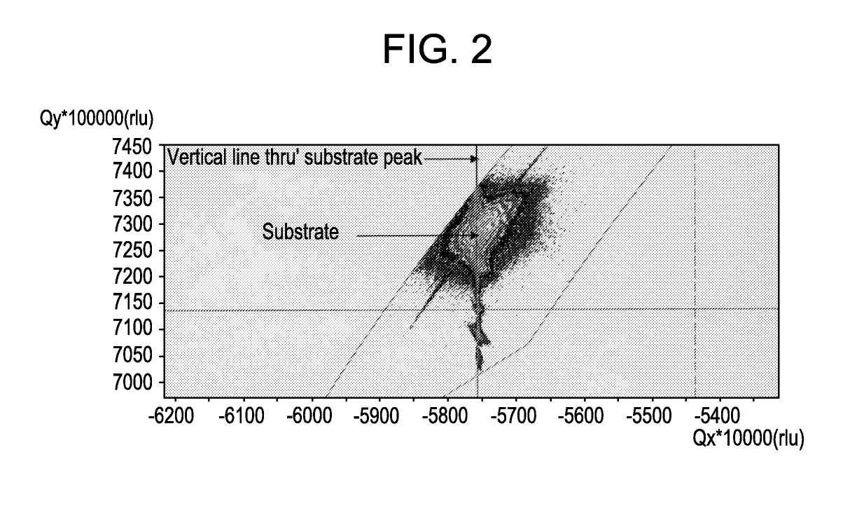

The GaN laser corresponding to Structure 2 may utilize at least one cladding layer comprising an AlGaInN/GaN super structure (SS), for example an n-type cladding layer 50. This enables lattice matching in one direction and strain minimization in the perpendicular direction to avoid misfit dislocation formation. As described above, any suitable composition of GaN and AlInN that is lattice matched (in one direction) to GaN can be utilized for the AlGaInN containing cladding layer to obtain the desired refractive index. However, higher AlInN content tends to degrade electrical conductivity, thus one may have to choose between having lower refractive index or having higher electrical conductivity. The average refractive index of the cladding layers that include an AlGaInN/GaN superstructure can be also controlled by choosing the ratio(s) of the AlGaInN sub-layer thickness to GaN sub-layer thickness. Exemplary thicknesses for AlGaInN and GaN sublayers in the superstructures forming the n-side cladding layer 50 are 7 to 12 nm (e.g., 10 nm) and 15 to 25 nm (e.g., 20 nm), respectively. In some embodiments, the composition of the AlGaInN layer is chosen to provide a photoluminescence emission wavelength of 336 nm at room temperature (22° C.). However, the photoluminescence emission wavelength can be shorter or longer (e.g., 330 nm, 340 nm or 350 nm), depending on the overall design and layer thickness; and the thickness ratio(s) can be varied as desired. Such superstructures give more freedom in the growth parameters, which helps improve the crystal quality of the cladding layers. However, because we found that the p-side cladding containing such superstructure is difficult to make with high levels of conductivity, it is preferable that the Example 2 embodiments according to Structure 2 utilize an AlGaInN/GaN superstructure on the n-side and an AlGaN/GaN superstructure on the p-side. In some exemplary embodiments the p-side cladding superstructure is a super lattice (SL) structure. In Example 2 embodiments the exemplary AlGaN sublayer(s) and the GaN sublayers of the p-side cladding 60 form a superlatice (SL) structure, and these AlGaN sublayers have an Al content of 10% or less (with an average Al content being 2 to 9 mole %). In some embodiments the thicknesses of the individual sub-layers of the super lattice structure of the p-side cladding 60 are about 2-5 nm, for example, 2, 2.5, 3 or 4 nm each. However, the Al content can be higher, or lower, depending on the design and coherency requirements. Because no indium is present in the p-side SL (p-side cladding layer 60), it can be grown at higher temperatures (greater than 800° C.), for example 850° C. to 1100° C. (e.g., 900-1000° C.), to obtain good p-side conductivity. By having the p-side cladding layer of a tensile strained AlGaN/GaN super lattice only on one side, the net strain is lowered because the compressive strain of MQWs and waveguide layers compensates the tensile strain of the p-side cladding layer, enabling one to avoid misfit dislocation formation. FIG. 2 shows the RSM (reciprocal space map) of a laser structure corresponding to the GaN semiconductor laser design of FIG. 1. It can be seen that the vertical line through the substrate peak passes through that of the layer and satellite peaks, indicating that all layers are coherent with the substrate. In the GaN laser corresponding to Structure 2, we found that it is preferable to make the p-side cladding 60 of the AlGaN/ GaN superstructure, having a total thickness greater than 500 nm (and preferably equal to or greater than 550 nm and less than 2000 nm). The thickness of the p-side cladding 60 is preferably greater than 700 nm, more preferably greater than 800 or 850 nm, (e.g., about 1 micron thick), in order to minimize or avoid optical loss due to absorption by the p-side metal contact layer 11. Typical thickness ranges for the p-side cladding 60 are 750 nm to 1200 nm, for example, 800 nm to 1100 nm.

More specifically, it is known that for GaN-based LDs emitting in the violet spectral range, the width (thickness) of the p-cladding layer is typically 400 nm or less (because it provides less resistance, which leads to a lower voltage drop). However, we discovered that situation is different for lasers emitting in the green spectral range. In general, at the longer operating wavelength optical confinement is weaker, because refractive index contrast between waveguiding and cladding layers is smaller. This causes stronger optical mode penetration into the metal layer 11 and so stronger optical loss due to optical absorption by this metal layer.

Following are design considerations for obtaining the desired refractive index contrast. In order to avoid relaxation in InGaN waveguiding layers and quantum wells, limited indium content in waveguiding layers should be used. The specific indium content depends on the thickness of the waveguide, but it is preferable that average In molar concentration is less than 10 mole %, preferably 3-6 mole %).

Also, in structure 2 embodiments, the average Al concentration in the p-side cladding layer 60 is limited; it is typically difficult to achieve good material quality and p-conductivity if the average Al concentration in the cladding layer 60 is higher than 10%. Preferably, if Al is utilized in the p-side cladding layer 60, the average Al concentration is 2 to 10 mole %, more preferably 2 to 7 mole % (e.g., about 4 to 6 mole %).

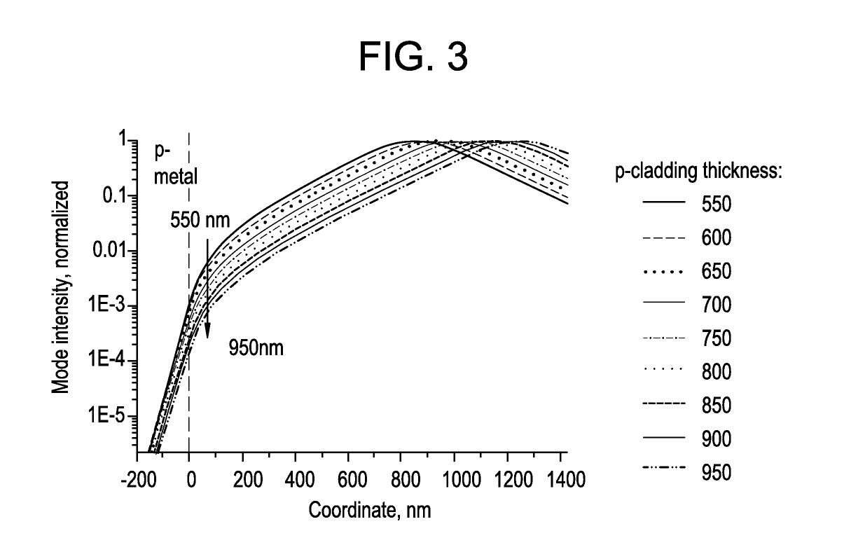

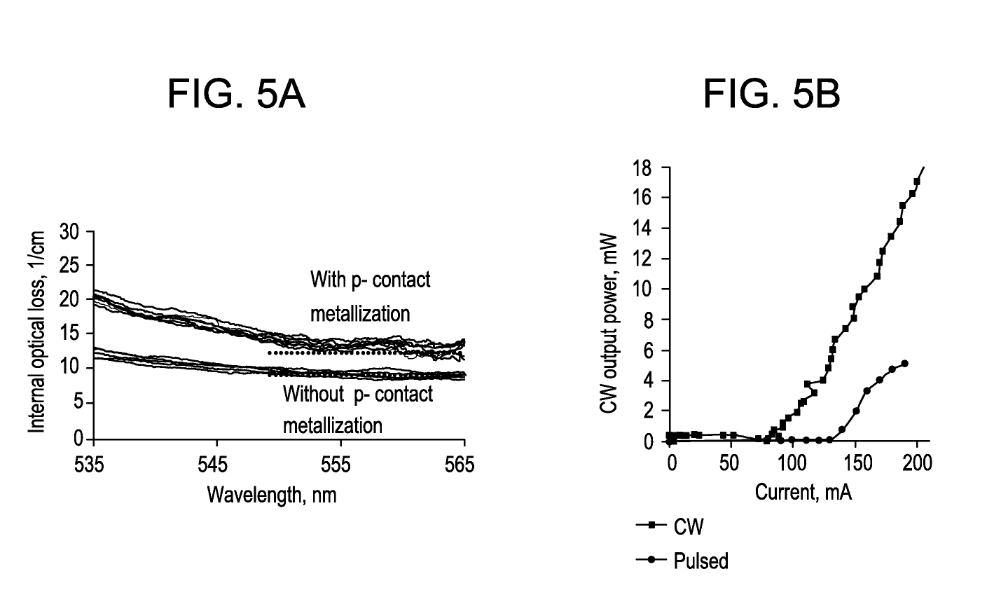

We discovered that a preferred way to reduce optical penetration to the p-side metal layer 11 is to increase the total thickness of the p-side cladding layer superstructure (or SL), i.e., the total thickness of the cladding layer 60. FIG. 3 illustrates simulated optical mode intensity of nine embodiments of the semiconductor GaN lasers corresponding to examples of Structure 2, and optical mode penetration to p-side metal layer 11 (the optical mode penetration corresponds to the portions of curves at the left of the dashed vertical line in FIG. 3). These embodiments are similar to one another, except for the thickness of the p-side cladding layer 60, which was changed incrementally from 550 nm to 950 nm. (Similar curves can be obtained for the embodiments corresponding to Structure 1.) More specifically, the vertical line in FIG. 3 corresponds to the interface between the p-metal layer 11 and the p⁺⁺ GaN contact layer 12. As stated above, the curves to the left of the dashed vertical line correspond to the penetration of the optical mode into the metal layer 11. The intersection of the nine curves with the vertical line corresponds to the amount of mode intensity at the interface between the p-side metal layer 11 and the p⁺⁺ GaN contact layer 12. Preferably, mode intensity at this interface is less than 1×10⁻³, preferably 2×10⁻³, and more preferably 5×10⁻⁴ or less, for example 2×10⁻⁴ or less. FIG. 3 illustrates that the increase of the cladding thickness helps to reduce optical mode penetration to the metal layer 11. For example, an increase of the p-side's super lattice cladding thickness from 550 nm to 850 nm substantially reduces the optical mode penetration to the p-metal layer 11, and thus reduces the optical loss in the p-metal layer 11. As shown in FIG. 5A, when the thickness of the p-side cladding layer 60 is about 850 nm, the addition of a metal layer 11 on top of the other p-side layers (in our examples 1 and 2 the metal layer 11 is placed on top of layer 12) causes only a very low internal optical loss (Δ<3 cm⁻¹, and preferably <2.5 cm⁻¹. Further reduction in loss is possible by an increase in the cladding layer thickness, for example to 900 or 950 nm (see FIG. 3), or for example to 1 μm (not shown). FIG. 5B illustrates that this lower optical loss, due to a relatively thick cladding layer 60 (in this embodiment, 850 nm), advantageously helps to achieve low threshold current, and also advantageously helps to achieve CW lasing generation (in addition to pulsed operation). (The threshold current of a 2×750 um stripe device that has structural parameters of Table 2A is 80 mA under pulsed operation and 130 mA under CW operation. LD lasing wavelength is 522 nm.) This high performance and continuous CW operation is not achievable with a relatively thin p-cladding layer (550 nm or thinner). The optical loss due to metallization is higher when the cladding thickness of the cladding layer 60 is reduced to 550 nm, and even higher when the thickness of this layer is below 500 nm. Therefore, it is preferable to use a p-side cladding layer 60 thickness of 500 nm or larger, more preferably at least 550 nm, and even more preferably 700 nm or larger (e.g., 750 nm or more). Most preferably the thickness of the p-side cladding layer 60 is 800 nm or larger. The thickness of the n-side layer 50 may be, for example, 1-2 μm.

### Example 3, Table 2B

This exemplary embodiment has a structure similar to that shown in Table 2A, but with a thinner p-side cladding 60. The specific parameters of one exemplary embodiment according to this structure are provided in Table 2B.

TABLE 2B

| Layer | Thickness | | Composition | Doping | Comments |
|---|---|---|---|---|---|
| p-Metal | | | | | |
| p-Contact | 25 | nm | GaN | p⁺⁺ doped | |
| p-spacer | 66 | nm | GaN | p⁺ doped | |
| p-side | 595 | nm | (2.5 nm Al_{0.1}Ga_{0.9}N/2.5 nm | p doped | In some |
| cladding, SL | | | GaN) × 119 | | embodiments this |
| | | | | | layer may |
| | | | | | comprise bulk p- |
| | | | | | Al_{0.05}Ga_{0.95}N layer |
| p-spacer | 51 | nm | GaN | p doped | Optional |
| p-SL | 90 | nm | (2 nm Ga_{0.88}In_{0.12}N/4 nm | p doped | |
| waveguide | | | GaN) × 15 | | |
| p-spacer | 5 | nm | GaN | p doped | Optional |
| Electron Block | 10 | | Al_{0.28}Ga₇₂N | p⁺ doped | |
| (EBL) | | | | | |
| Electron Block | 8 | nm | Al_{0.05}Ga_{0.93}In_{0.02}N | p⁺ doped | Optional |
| (EBL) | | | | | |
| MQW active | 50.8 | nm | (3.5 nm Ga_{0.7}In_{0.3}N/3.3 nm | Undoped | 2 or 3 QWs |
| region | | | GaN/8 nm | | |
| | | | Al_{0.05}Ga_{0.93}In_{0.02}N/3.3 nm | | |
| | | | GaN) × 2 | | |
| n-spacer | 13.7 | nm | GaN | n doped | Optional |
| Hole Block | 10 | | Al_{0.28}Ga₇₂N | n doped | Optional |
| (HBL) | | | | | |
| Hole Block | 8 | nm | Al_{0.05}Ga_{0.93}In_{0.02}N | n doped | Optional |
| (HBL) | | | | | |
| n-SL | 126 | nm | (2 nm Ga_{0.88}In_{0.12}N/4 nm | n doped | |
| waveguide | | | GaN) × 21 | | |
| n-spacer | 77 | nm | GaN | n doped | Optional |
| n-SL cladding | 1016.4 | nm | (23.1 nm GaN/7.7 nm | n doped | The AlGaInN |
| | | | AlGaInN) × 33, total TH | | composition |
| | | | | | should be such |
| | | | | | that it is lattice |
| | | | | | matched to |
| | | | | | GaN in the a- |
| | | | | | direction and |
| | | | | | have a PL |
| | | | | | emission of 336 nm |
| Buffer | 1050 | nm | GaN | n doped | |
| Substrate | 80 | microns | GaN | n doped | (20-21) |
| | | (60-90 | | | |
| | | microns) | | | |
| n-Metal | | | | | |

### Example 4, Table 2C

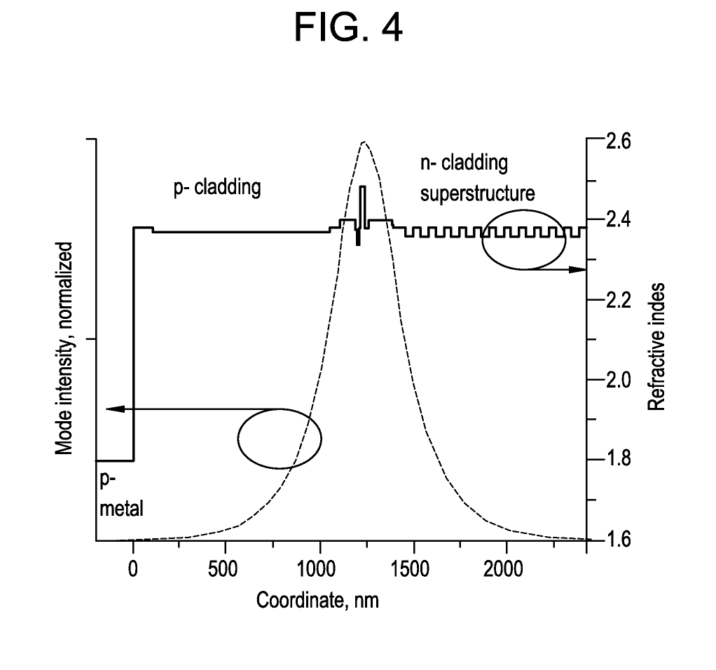

This exemplary embodiment has a structure similar to that shown in Table 2B, but with a thicker p-side cladding layer and thicker sublayers in the n-cladding layer 50. The specific parameters of one exemplary embodiment according to this structure is provided in Table 2C. The simulated optical mode profile and refractive index profile of this exemplary embodiment are illustrated FIG. 4, which also illustrates good optical confinement. structure.

TABLE 2C

| Layer | Thickness | | Composition | Doping | Comments |
|---|---|---|---|---|---|
| p Metal | | | | | |
| p Contact | 25 | nm | GaN | p⁺⁺ doped | |
| p-spacer | 66 | nm | GaN | p⁺ doped | |
| p-side | 950 | nm | (2.5 nm | p doped | In some |
| cladding, SL | | | Al_{0.1}Ga_{0.9}N/2.5 nm | | embodiments this |
| | | | GaN) × 119 | | layer may comprise |
| | | | | | bulk p-Al_{0.05}Ga_{0.95}N |
| | | | | | layer |
| p spacer | 51 | nm | GaN | p doped | Optional |
| p-side SL | 90 | nm | (2 nm Ga_{0.88}In_{0.12}N/4 nm | p doped | |
| waveguide | | | GaN) × 15 | | |
| p-side spacer | 5 | nm | GaN | p doped | Optional |
| Electron Block | 10 | | Al_{0.28}Ga₇₂N | p⁺ doped | |
| (EBL) | | | | | |
| Electron Block | 8 | nm | Al_{0.05}Ga_{0.93}In_{0.02}N | p⁺ doped | Optional |
| (EBL) | | | | | |
| MQW active | 50.8 | nm | (3.5 nm | Undoped | 2 or 3 QWs |
| region | | | Ga_{0.7}In_{0.3}N/3.3 nm | | |
| | | | GaN/8 nm | | |
| | | | Al_{0.05}Ga_{0.93}In_{0.02}N/3.3 nm | | |
| | | | GaN) × 2 | | |
| n-spacer | 13.7 | nm | GaN | n doped | Optional |
| Hole Block | 10 | | Al_{0.28}Ga₇₂N | n doped | Optional |
| (HBL) | | | | | |
| Hole Block | 8 | nm | Al_{0.05}Ga_{0.93}In_{0.02}N | n doped | Optional |
| (HBL) | | | | | |
| n-SL | 126 | nm | (2 nm Ga_{0.88}In_{0.12}N/4 nm | n doped | |
| waveguide | | | GaN) × 21 | | |
| n spacer | 77 | nm | GaN | n doped | Optional |
| n-SL cladding | 1120 | nm | (40 nm GaN/40 nm | n doped | The AlGaInN |
| | | | AlGaInN) × 14, total | | composition |
| | | | TH | | should be such |
| | | | | | that it is lattice |
| | | | | | matched to GaN |
| | | | | | in the a-direction |
| | | | | | and have a PL |
| | | | | | emission of 336 nm |
| Buffer | 1050 | nm | GaN | n doped | |
| Substrate | 80 | microns | GaN | n doped | (20-21) |
| | | (60-90 | | | |
| | | microns) | | | |
| n-Metal | | | | | |

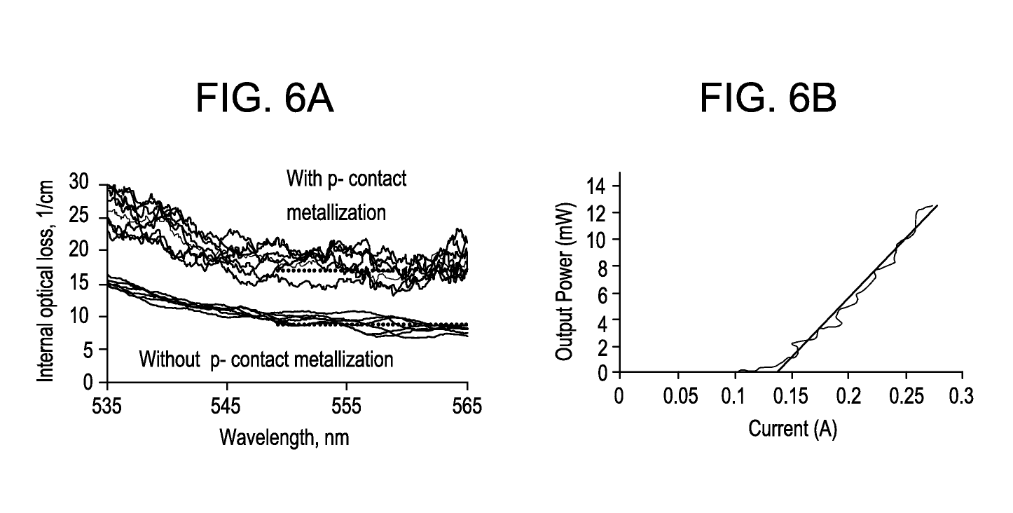

As discussed above, for group-III nitride LDs emitting at longer wavelength, optical confinement is, in general, weaker because the refractive index contrast between the waveguiding and cladding layers is relatively small. Because of this, if the design of the p-side-cladding layer is improper (i.e. the refractive index contrast is insufficient and/or the thickness of the cladding layer is not enough) the optical mode strongly penetrates toward the p-side metal layer. In the example corresponding to Table 2B, the thickness of the p-side cladding layer is smaller than that of the embodiment of Table 2A and, therefore, after p-side metallization, the optical loss is larger than that exhibited by the embodiment corresponding to Table 2A. As a result of reduction of thickness in the p-cladding layer 60 from 895 nm to 595 nm, the differential efficiency of lasing operation is reduced and the threshold current level is increased. This is illustrated by FIGS. 6A and 6B.

When the thickness of the p-side layer 60 is further reduced to 550 nm, the optical loss is significantly larger after p-metallization than the optical loss before p-metallization.

More specifically, FIG. 6A illustrates optical loss for the Structure 2 example with the p-cladding layer 60 of relatively low thickness (595 nm), before deposition of the p-side metal layer 11 on the p-side on the structure, and when the p-side metal layer 11 was added on top of the of the structure. As a result of reduction of thickness in the p-cladding layer 60 from 895 to 595 nm, the differential efficiency of lasing operation was reduced and the threshold current was increased, as we can see in the light output power vs. current graph shown in FIG. 6B. The threshold current of the device with ridge size of 2×750 μm was 140 mA under pulsed operation, and CW lasing was not achieved.

### Comparative Example

Table 3 provides the constructional parameters of the comparative GaN laser. This laser does not utilize indium in either the n-side or in the p-side cladding layer. The comparative example of Table 3 utilizes cladding layers that are AlGaN or AlGaN/GaN superlattice (SL) structures. When such cladding layers are utilized for making lasers in the green spectral range on a semipolar substrate, it is difficult to prevent misfit dislocation generation, which results in poor quality MQWs (multiple quantum wells) because the total accumulated strain-times-thickness exceeds the limits. (This happens because AlGaN is lattice mismatched to GaN. Our exemplary embodiments utilize indium to bring the lattice constant closer to that of GaN.)

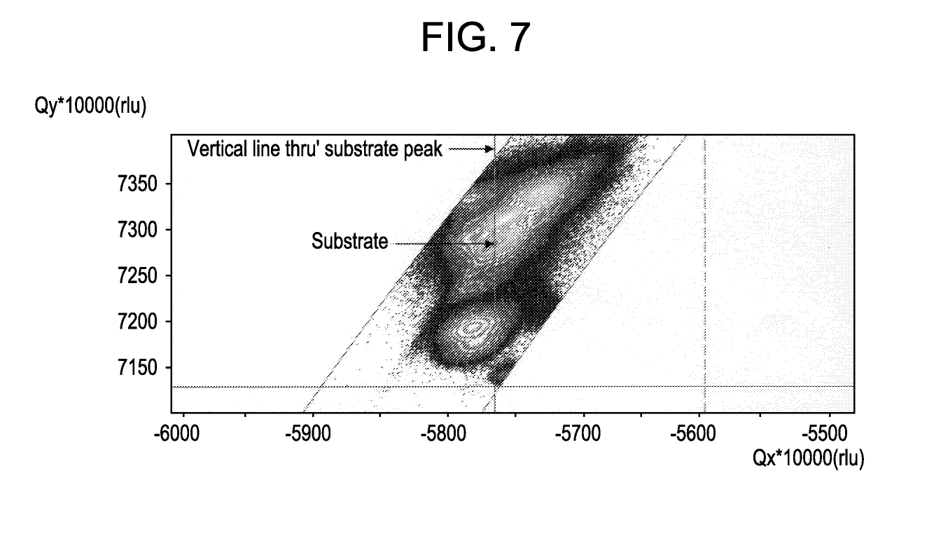

More specifically, in order to achieve lasing in the green wavelength range on a semipolar substrate, the comparative laser design of Table 3 utilizes thick n-side AlGaN or n-AlGaN/GaN (SL) cladding layers and p-side cladding layers of AlGaN or AlGaN/GaN SL layers. This comparative laser design results in misfit dislocations, and may cause defects and deterioration of the MQW active region, due to the relaxation of the tensile strained AlGaN or AlGaN/GaN superlattice (SL) structure of n-side cladding layers. For example, FIG. 7 shows a reciprocal space map (RSM) of a laser structure of Table 3, that utilizes n-side n-AlGaN and p-side p-AlGaN/p-GaN claddings. FIG. 7 illustrates that the layer and satellite peaks do not fall on the vertical line passing through the substrate peak. This indicates that unlike that of the embodiment of the lasers corresponding to FIG. 1 the in-plane lattice constant of the layers in the comparative laser of (Table 3) are different from that of the substrate, and therefore indicates relaxation of the cladding layers.

TABLE 3

| Layer | Thickness | | Composition | Doping | Comments |
|---|---|---|---|---|---|
| p-Metal | | | | | |
| p-Contact | 25 | nm | GaN | p⁺⁺ doped | |
| p-spacer | 66 | nm | GaN | p⁺ doped | |
| p-side, SL | 895 | nm | (2.5 nm | p doped | |
| cladding | | | Al_{0.1}Ga_{0.9}N/2.5 nm | | |
| | | | GaN) × 179 | | |
| p-spacer | 51 | nm | GaN | p doped | |
| p-SL | 90 | nm | (2 nm Ga_{0.88}In_{0.12}N/4 nm | p doped | |
| waveguide | | | GaN) × 15 | | |
| p-spacer | 5 | nm | GaN | p doped | Optional |
| Electron Block | 10 | | Al_{0.28}Ga₇₂N | p⁺ doped | |
| (EBL) | | | | | |
| Electron Block | 8 | nm | Al_{0.05}Ga_{0.93}In_{0.02}N | p⁺ doped | Optional |
| (EBL) | | | | | |
| MQW active | 50.8 | nm | (3.5 nm | Undoped | 2-3 QWs |
| region | | | Ga_{0.7}In_{0.3}N/3.3 nm | | |
| | | | GaN/8 nm | | |
| | | | Al_{0.05}Ga_{0.93}In_{0.02}N/3.3 nm | | |
| | | | GaN) × 2 | | |
| n-spacer | 13.7 | nm | GaN | n doped | Optional |
| Hole Block | 10 | | Al_{0.28}Ga₇₂N | n doped | Optional |
| (HBL) | | | | | |
| Hole Block | 8 | nm | Al_{0.05}Ga_{0.93}In_{0.02}N | n doped | Optional |
| (HBL) | | | | | |
| n side, SL | 126 | nm | (2 nm Ga_{0.88}In_{0.12}N/4 nm | n doped | |
| waveguide | | | GaN) × 21 | | |
| n-spacer | 77 | nm | GaN | n doped | |
| n-SL | 1000 | nm | (2.5 nm GaN/2.5 nm | n doped | |
| cladding | | | Al_{0.1}Ga_{0.9}N) × 200 | | |
| Buffer | 1050 | nm | GaN | n doped | |
| Substrate | 330 | microns | GaN | n doped | (20-21) |
| n-Metal | | | | | |

Unless otherwise expressly stated, it is in no way intended that any method set forth herein be construed as requiring that its steps be performed in a specific order. Accordingly, where a method claim does not actually recite an order to be followed by its steps or it is not otherwise specifically stated in the claims or descriptions that the steps are to be limited to a specific order, it is no way intended that any particular order be inferred.

It will be apparent to those skilled in the art that various modifications and variations can be made without departing from the spirit or scope of the invention. Since modifications combinations, sub-combinations and variations of the disclosed embodiments incorporating the spirit and substance of the invention may occur to persons skilled in the art, the invention should be construed to include everything within the scope of the appended claims and their equivalents.

1. A semiconductor laser having a structure comprising:
(a) GaN, AlGaN, InGaN, or AlN substrate;
(b) an n-doped cladding layer situated over the substrate;
(c) a p-doped cladding layer situated over the n-doped cladding layer;
(d) at least one active layer situated between the n-doped cladding layer and the p-doped cladding layer, wherein
at least one of said cladding layers contains indium and comprises a superstructure of quaternary/binary, ternary/binary and/or quaternary/ternary sublayers.

2. The semiconductor laser according to claim 1 wherein said at least one cladding layer that contains indium and comprises an superstructure of quaternary/binary, ternary/binary and/or quaternary/ternary sublayers has geometry and composition such that:
(i) the total lattice mismatch strain of the whole superstructure of said cladding layer relative to said substrate does not exceed 40 nm %; and/or
(ii) the total lattice mismatch strain of the semiconductor laser structure that is situated below said at least one cladding layer does not exceed 40 nm %; and or
(iii) the total lattice mismatch strain of the semiconductor laser structure that is situated below any higher cladding layer does not exceed 40 nm %’ and/or
(iii) the total lattice mismatch strain of the semiconductor laser structure does not exceed 40 nm %.

3. The semiconductor laser according to claim 1 wherein said at least one cladding layer has a superlattice structure and comprises of least one of the following sublayer pairs:
(i) AlInGaN and GaN, (ii) AlInGaN and AlGaN, (iii) AlInGaN and InGaN, (iv) AlInGaN/AlN, (v) AlInN/GaN, or combinations thereof.

4. The semiconductor laser according to claim 1 wherein the at least one of said cladding layers that contains indium and comprises a superstructure of quaternary/binary, ternary/binary and/or quaternary/ternary sublayer is an n-type cladding.

5. The semiconductor laser according to claim 1, wherein both p-type and n-type cladding layers contain indium.

6. The semiconductor laser of claim 1, wherein the at least one cladding layer comprises AlInGaN/GaN periodical structure; and another cladding layer is (i) an AlGaN/GaN superlattice; or (ii) GaN bulk material.

7. The semiconductor laser of claim 1, wherein the substrate comprises a semipolar plane of wurtzite crystal.

8. The semiconductor laser of claim 7, wherein the semipolar plane is situated at or is within degree 10 degrees orientation of the following planes: (11-22), (11-2-2), (20-21), (20-2-1), (30-31) or (30-3-1).

9. The semiconductor laser of claim 1 configured to emit light at wavelength in the range 510-540 nm.

10. A semiconductor laser comprising:
(i) GaN, AlGaN, InGaN, or AlN substrate;
(ii) an n-doped cladding layer situated over the substrate;
(iii) a p-doped cladding layer situated over the n-doped cladding layer;
(iv) at least one active layer situated between the n-doped and the p-doped cladding layer, and at least one of said cladding layers contains indium and comprises an alternating structure of least one of the following pairs: (i) AlInGaN and GaN, (ii) AlInGaN and AlGaN, (iii) AlInGaN and InGaN, (iv) AlInN and GaN, or (v) AlInGaN and AlN; and
the total lattice mismatch strain of the whole alternating structure of the cladding layer with the substrate does not exceed 40 nm %.

11. The semiconductor laser of claim 10, wherein (i) said substrate is GaN, and at least one cladding layer is a quaternary/binary superlattice-structure; or (ii) said substrate is GaN and the n-cladding layer is a superlattice-structure of AlGaInN/GaN.

12. The semiconductor laser of claim 10, wherein the p-doped cladding is AlGaN/GaN superlattice or GaN bulk material.

13. A semiconductor laser comprising:
(i) GaN, AlGaN, InGaN, or AlN substrate;
(ii) an n-doped cladding layer situated over the substrate;
(iii) a p-doped cladding layer situated over the n-doped;
(iv) at least one active layer situated between the n-doped and the p-doped cladding layer,
and at least one of said cladding layers comprises a super structure of AlInGaN/GaN, AlInGaN/AlGaN, AlInGaN//InGaN, AlInGaN/AlN, or AlInN/GaN.

14. The semiconductor laser of claim 13 wherein at least the n-doped cladding layer comprises a superlattice-structure of AlGaInN/GaN.

15. The semiconductor laser of claim 1, wherein said substrate is GaN with semipolar plane orientation.

16. The semiconductor laser of claim 1 wherein the p-doped cladding layer comprises a superlattice-structure of AlGaN/GaN.

17. The semiconductor laser according to claim 1 wherein the p-doped cladding layer has a thickness of at least 550 nm.

18. The semiconductor laser according to claim 17 wherein the p-doped cladding layer has a thickness of at least 600 nm.

19. The semiconductor laser according to claim 17 wherein the p-doped cladding layer has a thickness of at least 700 nm.
